(19) United States
(12) Patent Application Publication
(10) Pub. No.: US 2003/0141939 A1
(43) Pub. Date: Jul. 31, 2003

(54) TUNING OF MANIFOLD FILTER ASSEMBLY WITH FILTERS TUNED PRIOR TO CONNECTION TO THE MANIFOLD

(76) Inventor: Stephen Holme, San Ramon, CA (US)

Correspondence Address: J.E. Kosinski, Loral Space & Communications, Ltd., Suite 303, 655 Deep Valley Drive, Rolling Hills Estates, CA, 90274, US

(21) Appl. No.: 10/060,637

(22) Filed: Jan. 30, 2002

(51) Int. Cl. H03H 11/00

(52) U.S. Cl. 333/17.1; 333/134; 333/135

(57) ABSTRACT

A method of tuning individual filters in an assembly of filters connected to a manifold, such as a microwave multiplexer, prior to assembly of the multiplexer, is accomplished by energizing a subject filter to be tuned with an electromagnetic signal provided by a network analyzer. The filter is tuned by adjustment of a tuning component, such as a tuning screw within the filter, while the network analyzer presents the transfer function of the filter during the tuning process. To compensate for tuning effects of the other filters and of the manifold, which are manifested upon a connection of the filters to the manifold, the transfer function of the assembly is loaded into a computer of the network analyzer. Thereby, during a tuning of the filter, the presentation of the filter transfer function by the network analyzer includes the tuning effects of the rest of the assembly.

### BACKGROUND OF THE INVENTION

This invention relates to the tuning of each of a plurality of filters electromagnetically coupled to a common manifold, such as an assembly of filters in a manifold multiplexer and, more particularly, to a tuning of individual filters of the assembly, one filter at a time, while a representation of the spectral function of manifold plus filters is substituted for the remainder of the assembly.

Microwave circuitry for the processing and communication of electromagnetic signals may include an assembly of multiple filters coupled to a common manifold, as in the construction of a microwave signal multiplexer. Such circuitry finds use in numerous applications including a satellite communication system in which signals of differing frequency, located in separate channels, are combined into a single channel by a manifold multiplexer wherein a separate band pass filter is employed for coupling the signal of each of the channels to the manifold of the multiplexer.

In the usual construction of such an assembly of filters, the manifold is a section of waveguide such as a waveguide of rectangular cross-section having a pair of broad walls joined by a pair of narrow walls, wherein the width of the broad wall is typically double the width of a narrow wall. While it is possible to mount a filter to a narrow wall, the usual construction is to mount some of the filters to one of the broad walls, and the remainder of the filters to the other of the broad walls. This provides a compact configuration for the multiplexer. Each filter may have the shape of a cylindrical can in which a cylindrical sidewall is terminated by opposed and walls. In the mounting of a filter to the manifold, and end wall of the filter sits on a sidewall of the manifold, and a slot is located at the junction of filter and manifold for coupling a mode of propagation of electromagnetic signal in the filter to a mode of propagation of the electromagnetic signal in the manifold.

In the case of a communication system, the allocation of a band of frequencies for the communication of several signals may be divided into contiguous sub-bands, wherein each of several signal channels is tuned to a respective one of the sub-bands. Thus, in the foregoing example of the multiplexer, the filters are tuned to contiguous bands and, by virtue of their couplings to a common manifold, interact sufficiently such that the presence of one filter effects the tuning of each of the other filters.

Such interaction among the filters of the filter assembly has presented a disadvantage in the use of filter assemblies by requiring an arduous interactive procedure in the tuning of the individual filters of the assembly. It has been necessary to retune each of the filters to compensate for the effects of the tunings of the other filters until the desired response is achieved for each of the filters. Therefore, there is a need for a more efficient tuning procedure in which the filters can be tuned accurately, but without the need for time-consuming procedure of numerous iterations in the tuning process.

### SUMMARY OF THE INVENTION

The aforementioned disadvantage is overcome and other benefits are provided by a method of tuning individual ones of the filters in an assembly of a plurality of filters connected to a manifold. In accordance with the invention, the method enables a tuning of individual ones of the filters prior to connection of each of the filters to the manifold, this initial tuning of the filters being followed by a relatively small adjustment in tuning subsequent to attachment of the filters to the manifold. Each of the filters has two ports. It is noted that each of the filters operates in reciprocal fashion such that either one of the two ports may be regarded as the input port with the other port serving as the output port. To facilitate the description of the invention, one of the ports will be regarded as the input port and the other of the ports, which serves for connection of the filter to the manifold, will be regarded as the output port. Similarly, the manifold operates in reciprocal fashion such that one of the ports may be regarded as an input port and another of the ports may be regarded as an output port. For convenience in describing the invention, a filter is regarded as being connected to an input port of the manifold.

In the practice the invention, the method employs the following steps. Since each of the filters is tuned individually, one must first select a subject filter to be tuned, and after completion of the tuning of the subject filter, the process continues with the selection of another one of the filters to be tuned. The subject filter is energized with an electromagnetic signal applied by a network analyzer between input and output ports of the subject filter, the network analyzer being used for indicating the transfer function of the subject filter during the tuning process. The network analyzer has a detection circuit for detecting power and phase of a signal outputted by the subject filter, and further comprises a computer coupled to the detection circuit for determining the transfer function of the subject filter based on detected power and phase.

It is recognized that upon assembly of the subject filter plus the remaining filters to the manifold, that the microwave circuitry comprising the manifold plus all of the remaining filters effects the tuning of the subject filter. This tuning effect is compensated in the tuning process by loading into a computer of the network analyzer a transfer function of the assembly for the propagation of an electromagnetic signal between a first location on the manifold to an output port of the manifold, wherein the first location is at an interface between the subject filter and the manifold. Thus, during a tuning of the filter, there is a step of calculating, via the computer, a composite transfer function of propagation of the electromagnetic signal through the subject filter to the first location on the manifold and from the first location to the output port of the manifold.

The tuning of the subject filter is accomplished by adjustment of a filter component, such as a tuning screw, to provide a desired format to the composite transfer function. The foregoing steps of the tuning process is repeated for further ones of the filters to be tuned.

### BRIEF DESCRIPTION OF THE DRAWING

The aforementioned aspects and other features of the invention are explained in the following description, taken in connection with the accompanying drawing figures wherein:

FIG. 1 shows diagrammatically a microwave system including a multiplexer having an array of filters which may be tuned by a method in accordance with the invention;

FIG. 2 shows an alternative embodiment of a filter of FIG. 1;

FIG. 3 shows diagrammatically equipment employed in the tuning of a filter of FIG. 1; and

FIG. 4 is a diagram showing steps in practicing the method of the invention.

Identically labeled elements appearing in different ones of the figures refer to the same element but may not be referenced in the description for all figures.

### DETAILED DESCRIPTION OF THE INVENTION

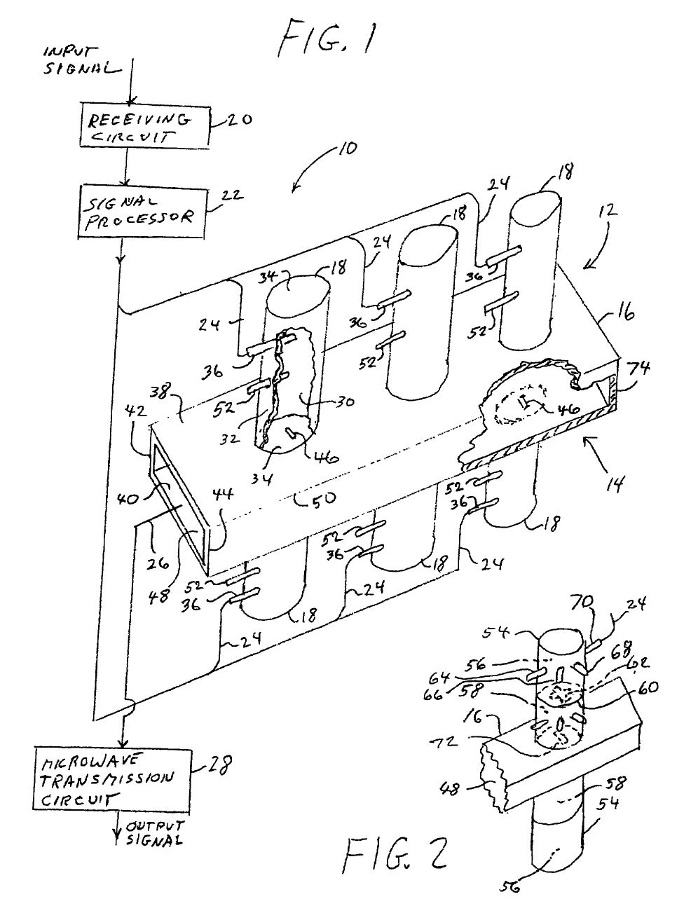

FIG. 1 presents a microwave electromagnetic system 10 including a multiplexer 12 useful for processing electromagnetic signals in a communication system, such as a satellite communication system. The multiplexer 12 comprises an assembly 14 of a manifold 16 and a plurality of filters 18 mounted to the manifold 16. During construction of the assembly 14, it is necessary to tune individual ones of the filters 18 to the pass bands of various signal channels to which respective ones of the filters 18 are to be tuned. This tuning of the filters is readily accomplished by the method of the present invention. It is noted that the system 10 with its multiplexer 12 is presented by way of example as a suitable equipment to be tuned by the present invention, it being understood that the methodology of the present invention is applicable to the tuning of other assemblies of interconnected filters. Before describing the methodology of the tuning process, further description is provided of the system 10.

The system 10 further comprises a receiving circuit 20 for receiving input microwave signals. Signals received by the circuit 20 are outputted to a signal processor 22 which may perform well-known functions, such as modulation and amplification functions by way of example. The signals outputted by the processor 22 are provided in separate signal channels, indicated by lines 24, directed to respective ones of the filters 18. Each of the filters 18 is operative to pass only its designated signal channel into the manifold 16, and is provided with a spectral characteristic which excludes the signal channels of the other ones of the filters 18. The manifold 16 serves to combine the individual signal channels into a composite microwave signal which is outputted via an output port 26 of the multiplexer 12 to transmission circuitry 28. The transmission circuitry 28 outputs a microwave signal for communication to a distant location.

For convenience in demonstrating the practice of the invention, each of the filters 18 is shown in FIG. 1 as having the shape of a cylindrical can with a cavity 30 defined by a cylindrical sidewall 32 bounded by an opposed pair of end walls 34. It is understood that other forms of filters may be tuned by the methodology of the present invention. Each of the filters 18 has an input port 36 connected to a respective one of the lines 24 for applying an input signal to the filter. The input port 36 to the filter 18 may have a well-known configuration such as a post or loop. The manifold 16 is constructed of a section of waveguide of rectangular cross-section, and comprises two opposed broad walls 38 and 40 joined by two opposed narrow walls 42 and 44. Three upper ones of the filters 18 are shown mounted to the upper broad wall 38, and another three lower ones of the filters 18 are shown mounted to be lower broad wall 40. The six filters are shown by way of example, it being understood that some other number of filters may be employed in the assembly 14. Also, while the filters are shown mounted to a broad wall of the manifold 16, a filter may also be mounted to a narrow wall of the manifold 16.

As a convenience in the mounting of the upper filters 18 to the upper broad wall 38, the cylindrical sidewall 32 in each of the upper filters 18 connects directly to the upper broad wall 38 of the manifold 16 so that the broad wall 38 also serves as the end of wall 34 in each of the upper filters 18. In similar fashion, the lower broad wall 40 serves as an end wall 34 in of the lower filters 18. A linear slot 46 extends through the end wall 34 in each of the filters 18 to communicate microwave energy between the cavity 30 and the interior space 48 of the manifold 16. Each slot 46 serves as an output port of its filter 18 and an input port to the manifold 16, and is oriented perpendicularly to an edge line 50 at the interface between a broad wall and a narrow wall of the manifold 16. The region of a slot 46 serves as an interface between a respective filter 18 and the manifold 16. Also included with each of the filters 18 is a tuning element, such as a tuning screw 52 disposed protruding through the sidewall 32. In the tuning process, the tuning screw 52 is advanced inwardly or outwardly through the sidewall 32 by rotation of the screw 52 to a location which produces the desired spectral response of the filter to a respective one of the signal channels.

By way of alternative embodiments to the construction of an individual one in of the filters 18, one or more of the filters 18 may be replaced with a filter 54, shown in FIG. 2, which filter, by way of example, has two cavities 56 and 58 separated by a transverse wall 60. By way of still further example, each of the two cavities 56 and 58 supports a dual mode of the electromagnetic excitation, the two cavities 56 and 58 being coupled by a crossed slot 62 located in the transverse wall 60. In the filter 54, three tuning screws 64, 66 and 68 are provided for tuning the cavity 56 and a separate set of the tuning screw 64, 66 and 68 is provided for the tuning of the cavity 58. In each of the cavities 56 and 58, the tuning screw 64 serves to tune the cavity to a first mode of vibration of an electromagnetic wave, the tuning screw 68 serves to tune the cavity to a second mode of vibration orthogonal to the first mode, and the tuning screw 66 is a mode coupling screw which serves to couple electromagnetic energy between the two modes. The input port 70 to the filter 54 may have a well-known configuration such as a post or loop. The output port of the filter 54 is a linear slot 72 passing between the cavity 58 and the interior space 48 of the manifold 16.

In the foregoing description of each of the filters 18, 54 and the manifold 16 various ones of the ports have been designated as an input port or an output port. It is to be understood that all of the filters as well as the manifold are reciprocal and operations such that the signal may flow in either direction and that, therefore, the designation of input port and output port are specific to the example of the system 10 in FIG. 1, and that the designation of the ports may be reversed in some other application of the multiplexer 12, such as in a situation, not shown, wherein the multiplexer 12 receives the signal at the port 26 and outputs the signal to various ones of the filters 18, 54. Also, the section of waveguide of which the manifold 16 is constructed may be open or closed at its ends, depending on the interconnection between the manifold and a further microwave element such as the transmission circuit 28. In the example presented in FIG. 1, one end of the section of waveguide is open to serve as the port 26 while the opposite and is closed by an end wall 74. The walls of the manifold 16 as well as the walls of the filters 18, 54 are constructed of electrically conductive material, such as copper or aluminum, by way of example.

With reference to FIG. 3, a network analyzer 76 is connected to a filter 18 of FIG. 1 to demonstrate the method of tuning a filter in accordance with the invention. The analyzer 76 is provided with a support 78 in the form of a stub waveguide for holding the filter 18 and for providing electromagnetic coupling between an output port of the filters 18 and the analyzer 76. The coupling with the filter 18 is through the slot 46 in the end wall 34 of the filter 18. The input port 36 of the filter 18 connects via a coaxial transmission line 80 to a port of the analyzer 76. The network analyzer 76 is a well-known, commercially available form of test equipment and includes a display 82, a computer 84, a data entry device 86 such as a keyboard, a signal generator 88, a detector 90 of amplitude and phase, and circuitry 92 for measuring the amplitude and phase imparted by the filter 18 to the signal applied to the filter 18 by the analyzer 76.

In the tuning of the manifold multiplexer, all of the filters connected to the manifold must operate simultaneously to provide a good impedance match at the output port of the multiplexer. Since each filter affects the ones contiguous in frequency around it, the present invention employs a network analyzer in a fashion which compensates for the effects of the other filters, and allows each filter to be tuned individually and later connected together with the other filters to the manifold with only minor adjustment of tuning being required thereafter. The computer 84 of the analyzer 76 incorporates software which can correct for measurement error in real time by using a series of standards to develop correction factors. In the practice of the present invention, the correction factors are adjusted so that the calculated transfer functions of the manifold and adjacent filters are included in the correction factors. As a result, as each filter is tuned, it appears to be connected to the ideal manifold and adjacent filters. By tuning each of the filters by a procedure wherein the filter appears to be connected to an ideal manifold and adjacent filters, the resulting set of tuned filters can later be connected together and provide the expected frequency response.

In the practice of the method of the invention, an equivalent circuit is constructed for the manifold 16 with the filters 18 connected thereto, the circuit including all of the filters except for the filter which is being subjected to the tuning process. The circuit is represented by a set of mathematical expressions which are fed into the analyzer 76 via the data entry 86. The computer 84 uses this data to formulate the correction factors which, in essence, compensate for the presence of the other frequency sensitive elements, namely the manifold 16 and the other filters 18, to provide for the frequency response, or transfer function, of the filter 18 in accordance with the fashion in which the filter will actually function when connected as a part of the assembly 14. The signal generator 88 of the analyzer 76 applies a test signal to the filter 18, which signal varies as a function of frequency so that measurement of filter response in terms of amplitude and phase can be made at numerous values of frequency. The difference between the signal applied by the signal generator 88 and the signal outputted by the filter 18, as detected by the detector 90, is measured by the measuring circuitry 92. Based on the measurements, the computer 84 presents the frequency response, or transfer function of the filter 18 on the display 82 for viewing by a person turning the filter 18. The person adjusts the tuning by turning the tuning screw 52 until the desired filter response is presented on the display 82. The procedure is then repeated for another one of the filters 18, the procedure continuing with successive ones of the filters 18 until all filters have been tuned.

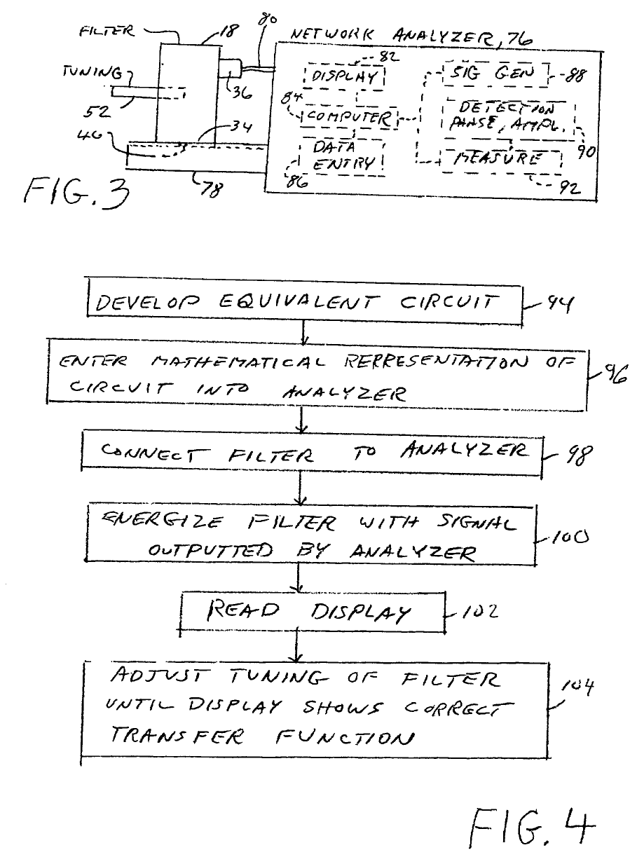

The foregoing procedure is outlined in FIG. 4 wherein the development of the equivalent circuit and is mathematical representation in shown at block 94, whereupon the data of the equivalent circuit is entered into the analyzer at block 96. The filter is connected to the analyzer at block 98 and is then energized with the test signal outputted by the analyzer at block 100. Thereupon, at blocks 102 and 104, the person conducting the tuning process watches the display and adjusts the tuning screw to obtain the desired transfer function of the filter under test.

It is to be understood that the above described embodiments of the invention are illustrative only, and that modifications thereof may occur to those skilled in the art. Accordingly, this invention is not to be regarded as limited to the embodiments disclosed herein, but is to be limited only as defined by the appended claims.

What is claimed is:

1. A method of tuning an individual filter prior to connection of the filter to a manifold in an assembly of a plurality of filters connected to the manifold, each of said filters having an input port and an output port wherein the output port serves for connection of the filter to the manifold, the method comprising steps of:
selecting a subject filter of said plurality of filters to be tuned;
providing a transfer function of said assembly for the propagation of an electromagnetic signal between a first location on said manifold to an output port of said manifold, said first location being at an interface between said subject filter and said manifold, there being further locations of other ones of the filters with the manifold;
energizing the subject filter with said electromagnetic signal by means of a network analyzer connected between the input and the output ports of the subject filter, the network analyzer having a detection circuit for detecting power and phase of a signal outputted by the subject filter, the network analyzer further comprising a computer coupled to the detection circuit for determining a transfer function of said subject filter based on detected power and phase;
loading into said computer the transfer function of said assembly;
calculating via said computer a composite transfer function of propagation of said electromagnetic signal through said subject filter to said first location on said manifold and from said first location to the output port of said manifold, the network analyzer being operative to present the transfer function of the subject filter as influenced by the presence of the tuning effects of the other filters and the manifold upon a construction of the assembly; and
tuning said subject filter to provide a desired format to the transfer function of the subject filter as presented by the network analyzer.

2. A method for tuning individual filters prior to connection of each of the filters is to a manifold in an assembly of a plurality of filters connected to a manifold, each of said filters having an input port and an output port wherein the output port serves for connection of the filter to the manifold, the method comprising steps of:
selecting a subject filter of said plurality of filters to be tuned;
providing a transfer function of said assembly for the propagation of an electromagnetic signal between a first location on said manifold to an output port of said manifold, said first location being at an interface between said subject filter and said manifold, there being further locations of other ones of the filters with the manifold;
energizing the subject filter with said electromagnetic signal by means of a network analyzer connected between the input and the output ports of the subject filter, the network analyzer having a detection circuit for detecting power and phase of a signal outputted by the subject filter, the network analyzer further comprising a computer coupled to the detection circuit for determining a transfer function of said subject filter based on detected power and phase;
loading into said computer the transfer function of said assembly;
calculating via said computer a composite transfer function of propagation of said electromagnetic signal through said subject filter to said first location on said manifold and from said first location to the output port of said manifold, the network analyzer being operative to present the transfer function of the subject filter as influenced by the presence of the tuning effects of the other filters and the manifold upon a construction of the assembly;
tuning said subject filter to provide a desired format to the transfer function of the subject filter as presented by the network analyzer; and
repeating said steps for further ones of said filters to be tuned.

3. A method according to claim 2 further comprising steps of connecting the filters to the manifold, and adjusting the tuning of each of the filters.

4. A method according to claim 3 wherein said step of tuning of the subject filter, the tuning is accomplished by adjustment of a tuning screw within the filter.

5. A method according to claim 3 wherein the subject filter is a dual mode filter having a cylindrical wall bounded by end walls, and, in said step of tuning of the subject filter, the tuning is accomplished by adjustment of a plurality of tuning screws within the filter.

6. A method according to claim 5 wherein each of the filters has a cylindrical wall bounded by end walls defining at least one filter cavity within each of the filters, the manifold is constructed as a section of waveguide bounded by sidewalls, and upon construction of the assembly to serve as a multiplexer, each of a plurality of the filters is mounted via an end wall to a sidewall of the manifold and is coupled by a slot to the manifold, and in said calculating step, the calculation of the composite transfer function includes the effects of the slots of respective ones of said filters on the propagation of electromagnetic signals within the multiplexer.

7. A method according to claim 2 wherein, upon construction of the assembly to serve as a multiplexer, individual ones of the filters are coupled by slots to the manifold, and in said calculating step, the calculation of the composite transfer function includes the effects of the slots on the propagation of electromagnetic signals within the multiplexer.
